(19) United States
(12) Patent Application Publication
(10) Pub. No.: US 2024/0339977 A1
(43) Pub. Date: Oct. 10, 2024

(54) AMPLIFIER WITH INPUT AND OUTPUT COMMON-MODE CONTROL IN A SINGLE AMPLIFICATION STAGE

(71) Applicant: TEXAS INSTRUMENTS INCORPORATED, Dallas, TX (US)

(72) Inventors: Dimitar Trifonov, Tucson, AZ (US); Chao-Hsiuan Tsay, Tucson, AZ (US); Chase Puglisi, Tucson, AZ (US)

(21) Appl. No.: 18/498,492

(22) Filed: Oct. 31, 2023

Related U.S. Application Data
(60) Provisional application No. 63/457,599, filed on Apr. 6, 2023.

(51) Int. Cl. H03F 3/45

(52) U.S. Cl. CPC H03F 3/45381; H03F 3/45636; H03F 2203/45008

(57) ABSTRACT

In some examples, an amplifier includes a pair of input differential transistors a pair of feedback transistors, a pair of current sources, a pair of gain setting resistors, and a tail current transistor. Control terminals of the feedback transistors are respectively coupled to first terminals of the input differential transistors. The pair of current sources are respectively coupled to the control terminals of the feedback transistors and the first terminals of the input differential transistors. The pair of gain setting resistors have first terminals that are respectively coupled to the second terminals of the input differential transistors. The pair of gain setting resistors have second terminals that are coupled to one another. The tail current transistor has a first terminal coupled to the second terminals of the gain setting resistors and a second terminal coupled to a DC supply.

### RELATED APPLICATION

This application claims the benefit of U.S. Provisional Application No. 63/457,599, filed on Apr. 6, 2023, the contents of which are hereby incorporated by reference in their entirety.

### BACKGROUND

An amplifier can be used to increase the power, voltage, or current of a signal. Amplifiers are used in many different applications in electronics. For example, an amplifier can be coupled to a magnetic sensor.

### SUMMARY

In some examples, an amplifier has a differential input and a differential output. The amplifier includes a first transistor having a first terminal, second terminal, and a control terminal. The first terminal of the first transistor is coupled to a first current source, and the control terminal of the first transistor corresponds to a first input terminal of the differential input. A second transistor has a first terminal, second terminal, and a control terminal. The first terminal of the second transistor is coupled to a second current source, and the control terminal of the second transistor corresponds to a second input terminal of the differential input. A third transistor has a first terminal, a second terminal, and a control terminal. The first terminal of the third transistor is coupled to the second terminal of the first transistor and corresponds to a first output terminal of the differential output, and the control terminal of the third transistor is coupled to the first terminal of the first transistor. A fourth transistor has a first terminal, a second terminal, and a control terminal. The first terminal of the fourth transistor is coupled to the second terminal of the second transistor and corresponds to a second output terminal of the differential output, and the control terminal of the fourth transistor is coupled to the first terminal of the second transistor. A first resistor has a first terminal and a second terminal. The first terminal of the first resistor is coupled to the second terminal of the first transistor and is coupled to the first terminal of the third transistor. A second resistor has a first terminal and a second terminal. The first terminal of the second resistor is coupled to the second terminal of the second transistor and is coupled to the first terminal of the fourth transistor. A current circuit is coupled to the second terminal of the first resistor and is coupled to the second terminal of the second resistor.

In some examples, an amplifier includes a pair of input differential transistors, a pair of feedback transistors, a pair of current sources, a pair of gain setting resistors, and a tail current transistor. The pair of input differential transistors each have first and second terminals and a control terminal. The control terminals of the pair of input differential amplifiers correspond to a differential input of the amplifier. The pair of feedback transistors each have first and second terminals and a control terminal. The first terminals of the feedback transistors correspond to a differential output of the amplifier, and the control terminals of the feedback transistors are respectively coupled to the first terminals of the input differential transistors. The pair of current sources are respectively coupled to the control terminals of the feedback transistors and the first terminals of the input differential transistors. The pair of gain setting resistors have first terminals that are respectively coupled to the second terminals of the input differential transistors are also respectively coupled to the differential output. The pair of gain setting resistors have second terminals that are coupled to one another. The tail current transistor has a first terminal coupled to the second terminals of the gain setting resistors and a second terminal coupled to a DC supply.

In some examples, an amplifier has a differential input and a differential output. The amplifier includes: a first transistor having a first terminal, a second terminal, and a control terminal. The first terminal of the first transistor is coupled to a first current source, and the control terminal of the first transistor corresponds to a first input terminal of the differential input. A second transistor has a first terminal, a second terminal, and a control terminal. The first terminal of the second transistor is coupled to a second current source, and the control terminal of the second transistor corresponds to a second input terminal of the differential input. A third transistor has a first terminal, a second terminal, and a control terminal. The first terminal of the third transistor is coupled to the second terminal of the first transistor, and the control terminal of the third transistor is coupled to the first terminal of the first transistor. A fourth transistor has a first terminal, a second terminal, and a control terminal. The first terminal of the fourth transistor is coupled to the second terminal of the second transistor, and the control terminal of the fourth transistor is coupled to the first terminal of the second transistor. A first resistor has a first terminal and a second terminal. The first terminal of the first resistor is coupled to the second terminal of the first transistor and is coupled to the first terminal of the third transistor. A second resistor has a first terminal and a second terminal. The first terminal of the second resistor is coupled to the second terminal of the second transistor and is coupled to the first terminal of the fourth transistor. The second terminal of the second resistor is coupled to the second terminal of the first resistor. A voltage output common-mode control circuit has an input and an output. The input of the voltage output common-mode control circuit is coupled to the differential output of the amplifier. A voltage input common-mode control circuit has an input and an output. The input of the voltage input common-mode control circuit is coupled to the output of the voltage output common-mode control circuit, and the output of the voltage input common-mode control circuit is coupled to the differential input of the amplifier.

### BRIEF DESCRIPTION OF THE DRAWINGS

FIG. 1A is a circuit diagram of an example amplifier architecture.

FIG. 1B is a circuit diagram of an example electrical system.

FIG. 2 is a circuit diagram of an example electrical system.

FIG. 3 illustrates some sample waveforms consistent with an example electrical system of FIG. 2.

FIG. 4 is a circuit diagram of another example electrical system.

FIG. 5 is a circuit diagram of another example electrical system.

FIG. 6 is a circuit diagram of another example electrical system.

FIG. 7 is a circuit diagram of another example electrical system.

FIG. 8 is a circuit diagram of another example amplifier architecture.

FIG. 9 is a circuit diagram of another example amplifier architecture.

### DETAILED DESCRIPTION

The drawings are not drawn to scale.

Some amplifier designs are not optimal on input common mode range and have trade-offs. For example, an amplifier design has a rail-to-rail operation, at the expense of higher and nonlinear noise. Another amplifier design includes a p-type metal-oxide semiconductor (PMOS) input differential pair and a charge pump, at the expense of higher noise. Additional shortcomings may arise due to the type of circuitry to which the amplifier is coupled. For example, where the amplifier is coupled to a magnetic sensor, certain additional challenges arise. The amplifier design that includes the PMOS input differential pair may be used to bias the magnetic sensor at a low common-mode voltage, but at the expense of low sensor gain. Also, magnetic sensors may have significant resistance drift over temperature, stress, and process variations. The resistance drift directly translates to the common-mode voltage range requirement for the coupled amplifier. The described examples address at least some of these shortcomings.

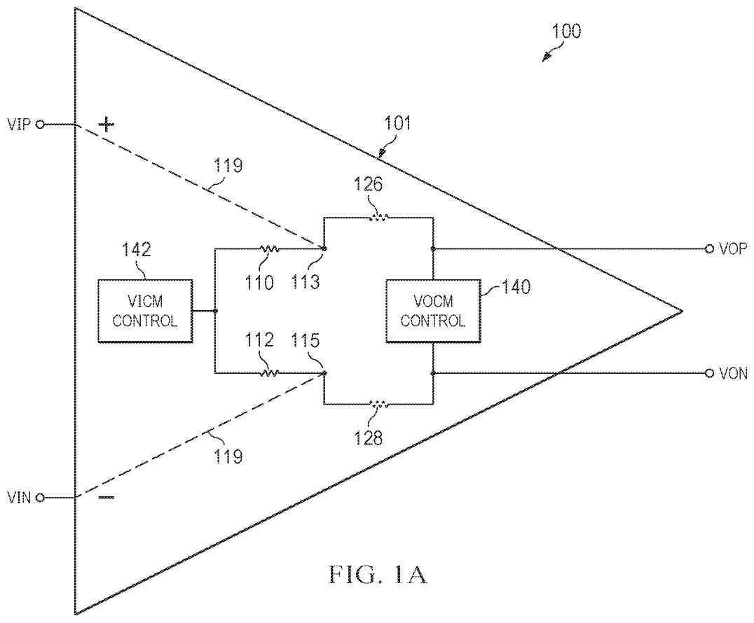

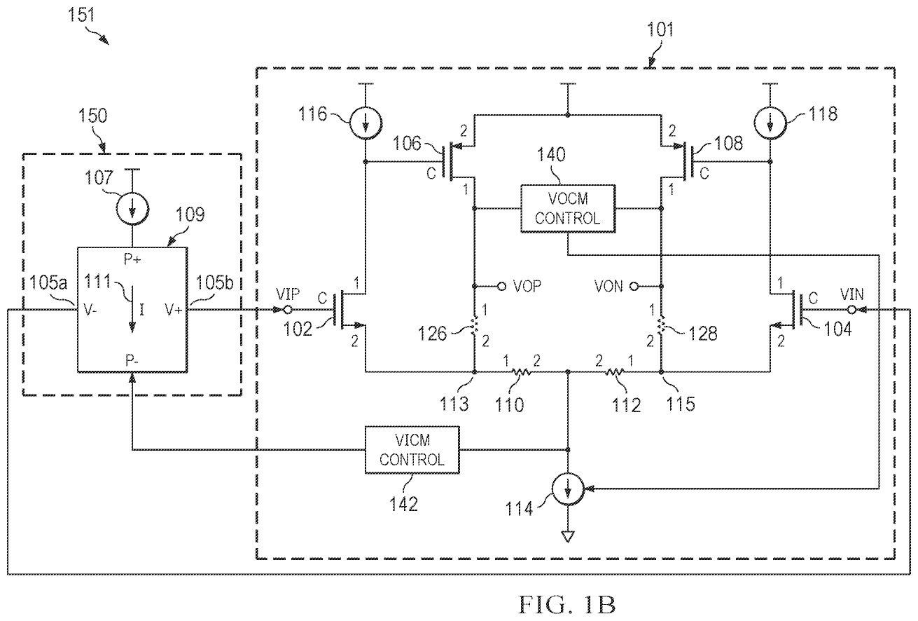

FIG. 1A is a circuit diagram of an example amplifier 101. The amplifier 101 has a first input terminal VIP (e.g., or positive terminal), a second input terminal VIN (e.g., negative terminal), and a differential output terminal VOP, VON. The amplifier 101 also includes resistors 110 and 112 and resistors 126 and 128. Nodes 113 and 115 that are internal to the amplifier 101 and also referred to as internal nodes 113 and 115. A voltage output common-mode (VOCM) control circuit 140 has input terminals coupled between the differential output terminal VOP, VON. A voltage input common-mode (VICM) control circuit 142 has a first terminal coupled to circuitry external to the amplifier architecture 100, and has a second terminal coupled to the VOCM control circuit 140. The dashed lines 119 represent additional circuit elements, examples of which are shown in the remaining figures.

As shown, resistors 110, 112, 126, and 128, each have first and second terminals. The first terminals of the resistors 126, 128 are coupled to the differential output terminal VOP, VON, respectively. The first terminals of resistors 110, 112 are coupled to the second terminals of resistors 126, 128, respectively. The second terminals of the resistors 110, 112 are coupled to the second terminal of the VICM control circuit 142.

A differential signal at the output terminal VOP, VON changes its magnitude responsive to a voltage difference between the first input terminal VIP and second input terminal VIN. The voltage difference between the first input terminal VIP and first input terminal VIN is an input differential voltage. The average of the two input voltages between VIP, VIN is the input common-mode voltage. Ideally, amplifiers have a large input common-mode voltage range over which noise at the output terminal VOP, VON remains below some threshold. Examples of the present description provide a new amplifier architecture where the amplifier has both the voltage output common-mode control circuit 140 and the voltage input common-mode control circuit 142, which operate continuously, for example.

In other amplifier approaches, attempting to implement voltage output common-mode control circuit and voltage input common-mode control circuit results in significant challenges. Accordingly, in FIG. 1A, the first and second input terminals VIP, VIN each feed an internal node 113, 115, respectively. The internal nodes 113, 115 are buffered by resistors 126, 128, respectively, to provide isolation between the input terminals (VIP, VIN) and voltage output common-mode circuit 140. The internal nodes 113, 115 are also buffered by resistors 110, 112, respectively, to provide isolation between the input terminals (VIP, VIN) and input common-mode control circuit 142. Thus, the resistors 110, 112, 126, 128 provide isolation between the voltage output common-mode circuit 140 and voltage output common-mode circuit 142 such that the voltage output common-mode circuit 140 and voltage output common-mode circuit 142 can provide continuous control. Thus, the voltage output common-mode circuit 140 provides a continuous time-varying control signal, and the input common-mode circuit 142 also provides a continuous time-varying control signal to resistors 110, 112. To help avoid instability issues, the voltage output common-mode circuit 140 and voltage input common-mode circuit 142 operate at different frequencies.

In some examples, resistors 126, 128 can be removed such that the internal nodes 113, 115 are shorted directly to the differential output terminal VOP, VON. In such examples, the amplifier 101 has unity gain, but can still benefit from a large input common-mode voltage range, over which noise at the output terminal remains below some predetermined threshold. In cases where the voltage output common-mode circuit 140 and voltage input common-mode circuit 142 operate continuously, performance of amplifier 101 is improved compared to other architectures. However, even if only one of the voltage output common-mode circuit 140 or voltage input common-mode circuit 142 is present, it can still aid performance in some regards. Additionally, the number of components is also relatively small for the amplifier 101 compared to other architectures. Therefore, the amplifier 101 has a small footprint on an integrated circuit and is relatively inexpensive to produce.

FIG. 1B is a circuit diagram of an example electrical system 151 that includes a sensor circuit 150 and amplifier 101. The sensor circuit 150 has a differential sensor output 105a, 105b. For example, in some instances, the sensor circuit 150 can be a magnetic Hall-effect sensor that includes a current source 107 and a thin metal strip 109 coupled to the current source 107. The current source 107 supplies a current 111 between two terminals on the top and bottom of the metal strip 109. When a magnetic field is perpendicular to the direction of the current 111, charge carriers in the current are deflected in the metal strip by the Lorentz force, producing a voltage difference between the two sides of the metal strip on differential sensor output 105a, 105b. This voltage difference (the Hall voltage) is proportional to the strength of the magnetic field. However, this output signal on differential sensor output 105a, 105b is often very small. Therefore, the amplifier 101 amplifies the output signal from the sensor circuit 150 so that other downstream circuit components can use the sensor output signal.

One nuance of this system is that the sensor circuit 150 can have significant resistance drift over temperature, stress, and process variation conditions. The resistance drift directly translates to a drift in the common-mode voltage output on differential sensor output 105a, 105b. For example, a Hall sensor resistance can vary by more than three times over a temperature range of −40° C. to 125° C. Thus, given a 5V supply, a Hall sensor resistance can provide a first common-mode output voltage of 1.4 V at −40° C., a second common-mode output voltage of 2.5 V at room temperature (e.g., 25° C.), and a third common-mode output voltage of 4.3 V at 125° C. Due to the large variance in the voltage difference on 105a, 105b (and equivalently voltage input common-mode for the amplifier 101), the amplifier 101 requires a wide input common-mode range.

To realize this wide input common-mode range, the amplifier 101 has a first input terminal VIP (e.g., or positive terminal), a second input terminal VIN (e.g., negative terminal), and a differential output terminal VOP, VON. The amplifier 101 also includes a pair of input differential transistors 102, 104; a pair of feedback transistors 106, 108; resistors 110 and 112; (tail) current circuit 114; current sources 116, 118; and optional resistors 126 and 128. The pair of input differential transistors 102, 104 each have first and second terminals and each have a control terminal. The control terminals of the pair of input differential transistors 102, 104 correspond to the differential input (VIP, VIN) of the amplifier. The pair of feedback transistors 106, 108 each have first and second terminals and each have a control terminal. The first terminals of the feedback transistors 106, 108 correspond to the differential output (VOP, VON) of the amplifier. The amplifier 101 also includes a voltage output common-mode (VOCM) control circuit 140 having a (first) VOCM terminal, a second terminal, and a third terminal. The amplifier 101 also includes a voltage input common-mode (VICM) control circuit 142 having a (first) voltage bottom common mode (VBCM) terminal and a second terminal. The VBCM terminal can drive a VICM voltage over VIP, VIN, wherein the VICM voltage is an average of voltages levels on VIP, VIN.

The control terminals of the feedback transistors 106, 108 are respectively coupled to the first terminals of the input differential transistors 102, 104. The control terminals of the feedback transistors 106, 108 and the first terminals of the input differential transistors 102, 104 are also coupled to the pair of current sources 116, 118, respectively. The differential output (VOP, VON) and the second terminals of the input differential transistors 102, 104 are also respectively coupled to first terminals of the first and second gain setting resistors 110, 112. Second terminals of the gain setting resistors 110, 112 are coupled to one another, and are coupled to a first terminal of the tail current circuit 114.

In some examples, the voltage output common-mode control circuit 140 has an input coupled to the differential output (VOP, VON, respectively) of the amplifier, and has a VOCM terminal coupled to a control terminal of the tail current circuit 114. Thus, the voltage output common-mode control circuit 140 can adjust a current through the tail current circuit 114 in response to a common-mode output signal on the differential output (VOP, VON) of the amplifier. Further, in some examples, the voltage input common-mode control circuit 142 has an input coupled to the second terminals of the gain setting resistors 110, 112, and has VBCM terminal coupled to the differential input (VIP, VIN) of the amplifier. For example, the VBCM terminal of the VICM control circuit 142 is coupled to the differential input (VIP, VIN) via the sensor circuit 150. Thus, the voltage input common-mode control circuit 142 can adjust the input common-mode voltage of the differential input (VIP, VIN) of the amplifier responsive to a current and/or voltage level on the tail current circuit 114, and independent of the input signal level.

Compared to other architectures, the amplifier 101 can receive a wider input common-mode signal range on the differential input (VIP, VIN) and can deliver an output signal with low noise on the differential output (VOP, VON). In some examples, the amplifier 101 can also deliver an output signal with a high gain. Thus, the performance of amplifier 101 is improved compared to other architectures in some regards. The ratio of the resistance of resistors 110, 112 to the resistance of resistors 126, 128 sets the amplifier closed-loop gain (e.g., the closed-loop gain is 1+Resistance126/Resistance110). Thus, in some examples the resistance of 126, 128 is larger than the resistance of 110, 112 to realize a high gain. However, in other examples, resistors 126, 128 are omitted and the amplifier 101 has a unity gain. Additionally, the number of components is also relatively small for the amplifier 101 compared to other architectures. Therefore, the amplifier 101 has a small footprint on an integrated circuit and is relatively inexpensive to produce.

Although FIG. 1B shows an example where the sensor circuit 150 is a Hall-effect sensor, the sensor circuit 150 can be some other type of sensor that provides a differential input signal to the amplifier 101. For instance, other sensors can include a magneto-resistance sensor or gauge-stress sensor, among others. Further, a common-mode input voltage on VIP, VIN is described, and input differential transistors 102, 104 are illustrated as metal oxide semiconductor field effect transistors (MOSFETs). However, in other examples, the sensor can provide a common-mode input current, and bipolar junction transistors (BJTs) or other transistors can be used to sense this common-mode input current. For example, any of the MOSFETs in FIG. 1B can be replaced with BJTs.

Further still, within each pair of transistors 102, 104 and/or 106, 108 and/or resistors 110, 112, and/or 126, 128, the transistors and/or resistors of the pair are “matched” to one another, subject to normal process/device variation due to fabrication tolerances. Thus, matched transistors have the same width to length (W/L) ratios and same device characteristics (e.g., threshold voltages) as one another. For example, the pair of input differential transistors 102, 104 share a first W/L ratio as one another, and the pair of feedback transistors 106, 108 share a second W/L ratio as one another, and so on. The first W/L ratio can be the same as or different from the second W/L ratio, and so on. Matched resistors of a pair have equal resistances and similar geometries, subject to normal process/device variation due to fabrication tolerances. For example, the pair of resistors 110, 112 share a first resistance as one another, and the pair of resistors 126, 128 share a second resistance as one another, and so on.

In some examples the amplifier 101 can be implemented as an integrated circuit (IC) arranged on one or more semiconductor substrates. The amplifier 101 can be a standalone chip, die, or IC. In other examples, the amplifier 101 can be included as part of a three-dimensional IC where multiple dies are stacked within a single IC package. In still other examples, the amplifier 101 can be distributed among multiple chips and/or discrete components, which are coupled together on a printed circuit board. A “semiconductor substrate” can be a monocrystalline silicon substrate, a silicon on insulator (SOI) substrate, and/or can include other semiconductor materials, such as gallium arsenide (GaAs), indium gallium arsenide (InGaAs), and germanium (Ge), among others. In some examples, the sensor circuit 150 and amplifier 101 can be included on a single chip, die, or IC package. Alternatively, the sensor circuit 150 and amplifier 101 can also be implemented as separate chips and/or IC packages coupled together on a printed circuit board.

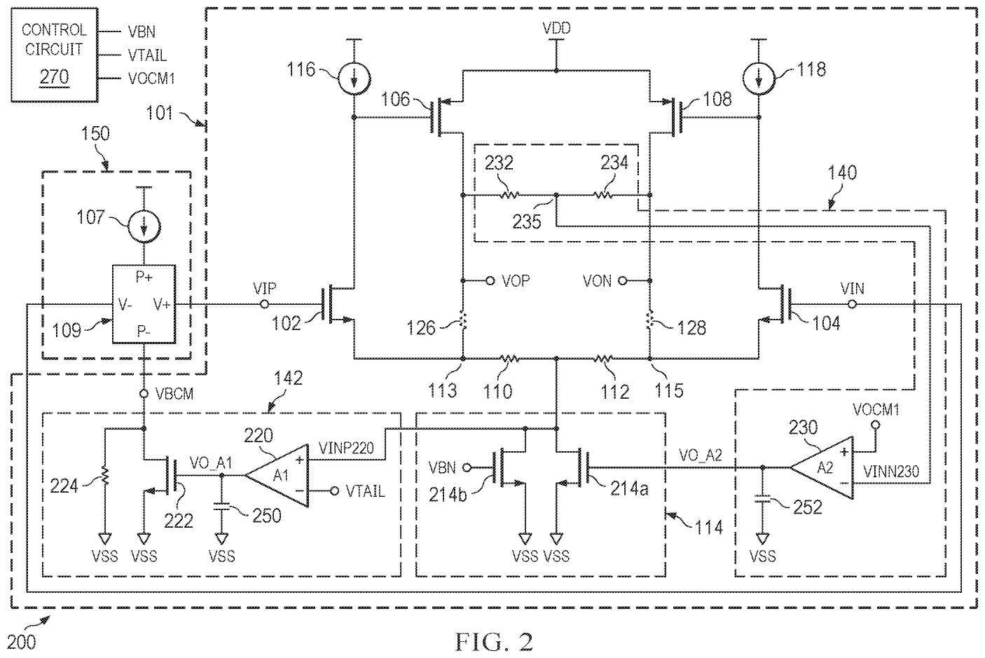

FIG. 2 illustrates another circuit diagram for an electronic system 200. The sensor circuit 150 and amplifier 101 are generally consistent with the features of sensor circuit 150 and amplifier 101 of FIG. 1A and FIG. 1B, with like reference numerals being labeled with the same reference numbers, but including additional features relative to sensor circuit 150 and amplifier 101.

The amplifier 101 of FIG. 2 has a differential input VIP, VIN and a differential output VOP, VON. The amplifier 101 includes a first transistor 102, a second transistor 104, a third transistor 106, and a fourth transistor 108. The amplifier 101 also includes a first resistor 110, a second resistor 112, a third resistor 126, and a fourth resistor 128. A tail current circuit is also present, and can include a first tail current transistor 214a and a second tail current transistor 214b. A first current source 116 and a second current source 118 are also present. In some examples, the first and second transistors 102, 104 can be referred to as a pair of “input differential transistors”; the third and fourth transistors 106, 108 can be referred to as a pair of “feedback transistors”; and resistors 110, 112, 126, and 128 can be referred to as “gain setting resistors”.

In FIG. 2's example, the output common-mode control circuit 140 includes output common-mode control amplifier 230, output common-mode sensing resistors 232, 234, and capacitor 252. The output common-mode sensing resistors 232, 234 are coupled to amplifier 230 at common output node 235. The input common-mode control circuit 142 includes input common-mode control amplifier 220, sensor bottom bias control transistor 222, start-up resistor 224, and capacitor 250.

Each of the transistors 102, 104, 106, 108 has a first terminal, second terminal, and a control terminal. The first terminals of the transistors 102, 104 are coupled to current sources 116, 118, respectively. The control terminals of transistors 102, 104 correspond to first input terminal (VIP) and second input terminal (VIN) of the differential input, respectively. The second terminals of transistors 102, 104 are coupled to internal nodes 113, 115, respectively. The first terminals of transistors 106, 108 are coupled to the second terminals of transistors 102, 104, respectively, via resistors 126, 128, respectively. The first terminals of transistors 106, 108 also correspond to first output terminal (VOP) and second output terminal (VOP) of the differential output, respectively. The control terminals of transistors 106, 108 are coupled to the first terminals of transistors 102, 104, respectively.

In the illustrated example, the transistors are illustrated as MOSFETs. MOSFETS tend to provide lower power consumption than some other approaches. Thus, in the illustrated example of FIG. 2, transistors 102, 104, 214a, 214b, and 222 are n-type MOS (NMOS) transistors, and transistors 106 and 108 are p-type MOS (PMOS) transistors. Further, in the illustrated example, each “first terminal” for these transistors is a drain, each “second terminal” is a source, and each “control terminal” is a gate. In other examples, complementary implementations can be used where N-type transistors (e.g., 102, 104, 214a, 214b, and 222) can be replaced with P-type transistors, and P-type transistors (e.g., 106 and 108) can be replaced with N-type transistors. Other transistors, such as bipolar junction transistors (BJT), fin-field-effect transistors (FinFETs), and/or junction field effect transistors (JFETs), among others, could also be used. When other transistors are used, the first terminal, second terminal, and control terminal are suitably changed. For example, when the transistors are BJTs, the first terminal can be an emitter (or collector), the second terminal can be a collector (or emitter), and the control terminal can be a base. When BJTs are used, they tend to provide lower noise at the differential output than some other approaches.

The first resistor 110 has a first terminal and a second terminal. The first terminal of resistor 110 is coupled to the second terminal of transistor 102, and is coupled to the first terminal of transistor 106 via resistor 126. The second resistor 112 has a first terminal and a second terminal. The first terminal of resistor 112 is coupled to the second terminal of transistor 104, and is coupled to the first terminal of transistor 108 via resistor 128. The first and second tail current transistors 214a, 214b are coupled to the second terminals of the resistors 110, 112.

During operation, the amplifier 101 receives a differential input signal from the sensor circuit 150 on the differential input VIP, VIN. In response to this differential input signal, the amplifier outputs a differential output signal on VOP, VON. The differential output signal on VOP, VON has a larger magnitude than the differential input signal on VIP, VIN.

The input differential transistors 102, 104 and gain setting resistors 110, 112 set the input noise level. The gain setting resistors 110 and 112 set the amplifier closed-loop gain to 1+Resistance126/Resistance110. Feedback transistors 106 and 108 direct the differential signal current through resistors 126, 128 and 110, 112. Current sources 116 and 118 set the trans-conductance of transistors 102 and 104. The tail current transistors 214a and 214b have multiple functions including: setting a DC bias current of transistors 106 and 108 and thereby setting an output common-mode voltage on the VOCM terminal. An input common-mode voltage on VBCM terminal changes in response to voltage VO_A1 on gate of transistor 222. Moreover, transistor 214b provides the constant biasing current to control terminal VBN (e.g., the voltage provided on VBN is fixed/constant). The current through transistor 214a is responsive to the output common-mode voltage on VOP, VON. Thus, if output common-mode voltage increases, amplifier 230 provides less gate drive voltage on gate of 214a, pulling less current and consequently pulling VOP, VON towards VSS. In contrast, if output common mode voltage decreases (e.g., lower temperature), amplifier 230 provides a more gate drive voltage on gate of 214a, pulling more current and consequently pulling VOP, VON towards VDD. As shown, a positive power terminal (P+) of the sensor circuit 150 couples to a first terminal of current source 107, and a negative power terminal (P−) couples to the drain/collector of the transistor 222. A second terminal of the current source 107 couples to a voltage supply (e.g., that provides a supply voltage VDD). Signal output terminals V+, V−, of the sensor circuit 150 couple to the control terminals of transistors 102 and 104.

A control circuit 270 provides various voltage references. For example, control circuit 270 can provide a reference voltage output common mode signal on a reference voltage output common mode terminal (VOCM1). Control circuit 270 can also provide a reference voltage tail signal on a reference voltage tail terminal (VTAIL). Control circuit 270 can also provide a reference bias voltage signal on control terminal of transistor 214b. The control circuit 270 can take various forms. For example, the control circuit can include a bandgap reference circuit and/or a resistive network.

In an example, the voltage output common-mode circuit 140 and voltage input common-mode circuit 142 operate continuously. Briefly, when the electronic system 200 powers on, the circuit components in the amplifier 101 start working together. Because the VICM circuit 142 and VOCM circuit 140 provide feedback/control immediately upon start-up, there's a potential instability problem. Therefore, first settling capacitor 250, second settling capacitor 252, resistor 224, and bias current source 214b help control the start-up sequence. The amplifier 101 turns on the input common-mode feedback loop 142 first. After the input common-mode circuit 142 settles, then the output common-mode feedback circuit 140 turns on. After start up, both feedback loops 140, 142 work continuously.

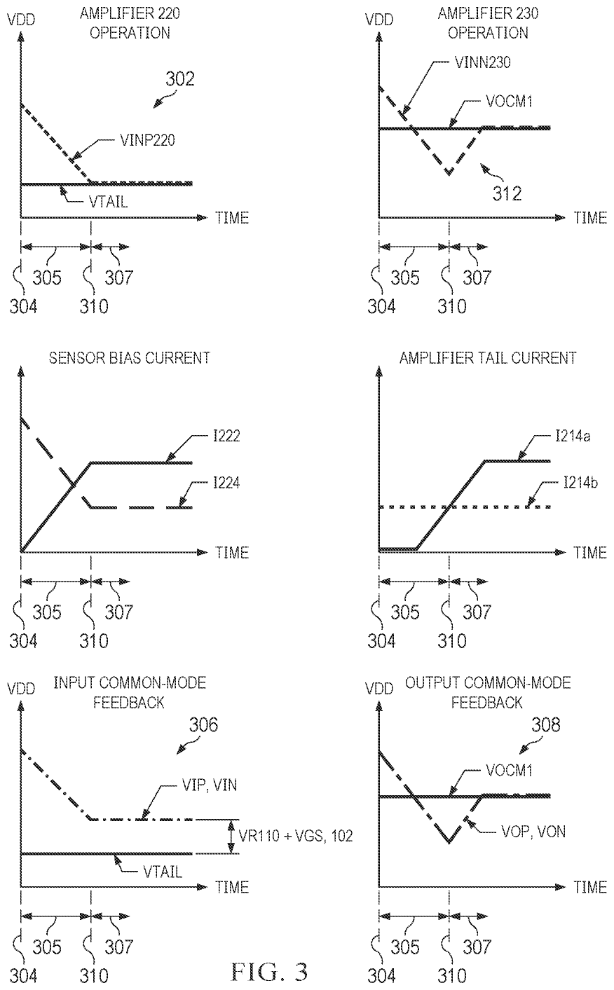

More particularly, the output common-mode circuit 140 provides a time-varying control signal VO_A2 to the control terminal of transistor 214a in response to the differential output voltage on VOP, VON. Responsive to the voltage output common-mode circuit 140 providing the time-varying control signal VO_A2, the input common-mode circuit 142 provides a time-varying control signal VO_A1 to the control terminal of transistor 222. To help avoid instability issues, the voltage output common-mode circuit 140 and voltage input common-mode circuit 142 operate at different frequencies. Accordingly, the amplifier 101 includes a first settling capacitor 250 and a second settling capacitor 252. The first settling capacitor 250 has a smaller capacitance value than the second settling capacitor 252. As a result, the frequency of the time-varying control signal VO_A2 at the control terminal of transistor 214a is different from the frequency of the time-varying control signal VO_A1 at the control terminal of transistor 222. In an example, the settling capacitors 250, 252 cause operation of the amplifier 101 to follow the order of start-up, input common-mode settling, and then output common-mode settling, as described below with regards to FIG. 3.

To describe functionality of FIG. 2's system, reference is now made to the example timing diagram of FIG. 3 concurrently with FIG. 2. In FIG. 3, the 1222, 1224, 1214a, 1214b represent the current through transistor 222, resistor 224, transistor 214a, and transistor 214b, respectively. Further, double-tailed arrow VR110+VGS, 102 (see 320) represents the voltage drop over resistor 110 plus the gate-source voltage over transistor 102. In FIG. 3, start-up occurs at 304, followed by input common-mode settling 305, and output common-mode settling 307. In an example, during start up, the voltage input (VINP220) on the positive terminal of amplifier 220 is greater than VTAIL (see 302). Therefore, at power up, transistor 222 is in off state, and the start-up resistor 224 takes all sensor bias current 107 and raises the sensor bottom bias to VDD (see time 304). At the start and during input-common-mode settling 305, NMOS transistors 102, 104 are on, and PMOS transistors 106 and 108 are off. At start up, transistor 214a is also in off state. Current source 214b is designed to support a portion of current sources 116 and 118. As the amplifier 101 starts up, resistors 126, 128 sense nearly VDD, so only voltage input common-mode circuit 142 is operating. Thus, the input common-mode voltage is near VDD, and the gate-source voltage (VGS) drop on transistor 102 is ˜0.6V, so terminal 2 of resistor 126 senses nearly VDD. Resistors 232 and 234 sense nearly VDD. Node 235 senses nearly VDD. VINN230 is greater than VOCM1 so VO_A2 is at ground. Transistor 214a stays in the off state.

After input common-mode voltage 306 in FIG. 3 settles, then 126, 128 sense a low voltage that turns on the voltage output common-mode circuit 140. As a result, the transistor 214b provides a constant biasing current and limits the biasing currents of transistors 102 and 104, such that output common-mode feedback from VOCM circuit starts later due to PMOS transistors 106 and 108 in off state. The voltage VINP220 is close to the positive supply so the amplifier 220 turns on the transistor 222. The bias current 116 sets the transistor 102 voltage drop between control terminal and second terminal, thus the amplifier 101 output common-mode voltage decreases when its input common-mode voltage decreases. (See 306, 308). The amplifier input common-mode voltage settles when the voltage (VINP220) at drain of transistor 214a equals to the threshold (VTAIL) of amplifier 220 (see time 310).

After the amplifier input common-mode settles (at time 310), the output common-mode voltage (VOP, VON) is below the threshold (VOCM) of amplifier 230 (see 312). As a result, the amplifier 230 turns on the transistor 214a. The biasing currents of transistors 102 and 104 increase to the bias current level set by the current sources 116 and 118, so the drain voltage of transistors 102 and 104 decreases. The transistors 106 and 108 turn on with the lower input biasing voltage. The current of transistor 214a keeps increasing until the output common-mode voltage on VOP, VON equals to the threshold (VOCM) of amplifier 230. Thus, the additional current of transistor 214a goes to transistors 106 and 108. The input common-mode control 142 stabilizes the gate voltage of transistors 102 and 104 by the bottom voltage buffering from the transistor 222. The output common-mode control circuit 140 stabilizes the drain voltage of transistors 106 and 108 by adjusting the bias currents of transistors 106 and 108.

Thus, the example of FIG. 2 shows an amplifier architecture with ideal biasing current sources. VTAIL sets the amplifier input common-mode voltage using the equation:

VICM=(VIP+VIN)/2=VGS_102,104+V_110+VTAIL, (1)

where VGS_102, 104 is the gate to source voltage (or base to emitter voltage) of transistor 102 and 104, and V_110 is the voltage drop across resistor 110. VOCM sets the output common-mode voltage. VOCM=(VOP+VON)/2. Resistors 110, 112, 126, and 128 set the closed-loop gain. Amplifier 220 provides input common-mode control (VIP/VIN), and amplifier 230 provides output common-mode control (VOP/VON).

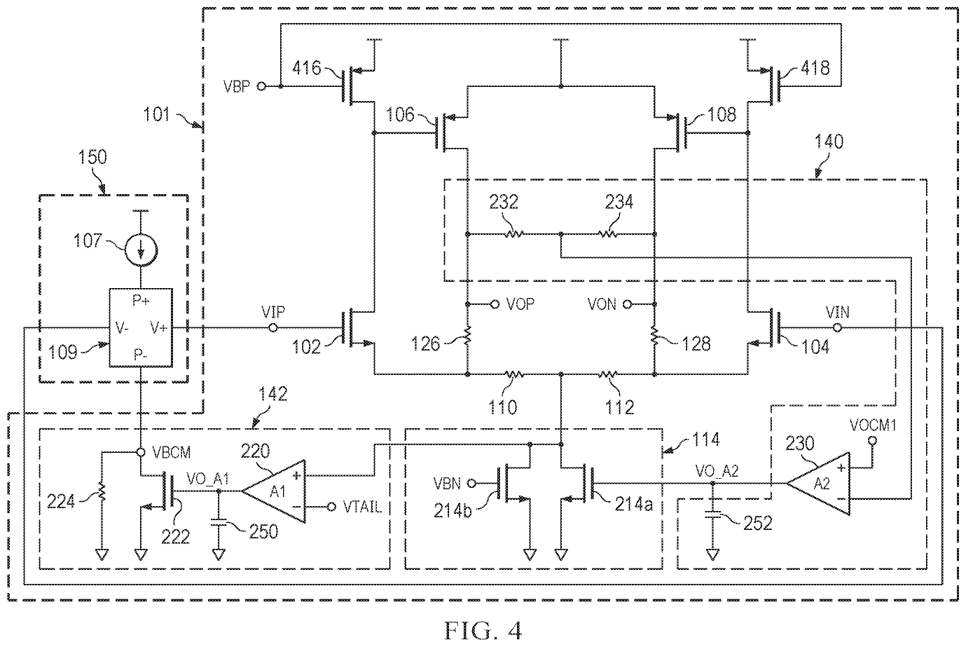

Other examples may further improve the amplifier performance, for example by reference to FIGS. 4-9.

FIG. 4 illustrates another circuit diagram for an electrical system. The sensor circuit 150 and amplifier 101 are generally consistent with the features of FIGS. 1-2, with like features being labeled with the same reference numbers. However, the system of FIG. 4, includes additional features relative to FIGS. 1 and 2. As shown, FIG. 4 is substantially the same as FIG. 2, but FIG. 4 shows transistors 416, 418 in place of current sources 116, 118 of FIG. 2. Although FIG. 4 shows an example where current sources 116, 118 are implemented as transistors 416, 418, in other examples, cascode amplifiers or other circuits can be used as current sources 116, 118.

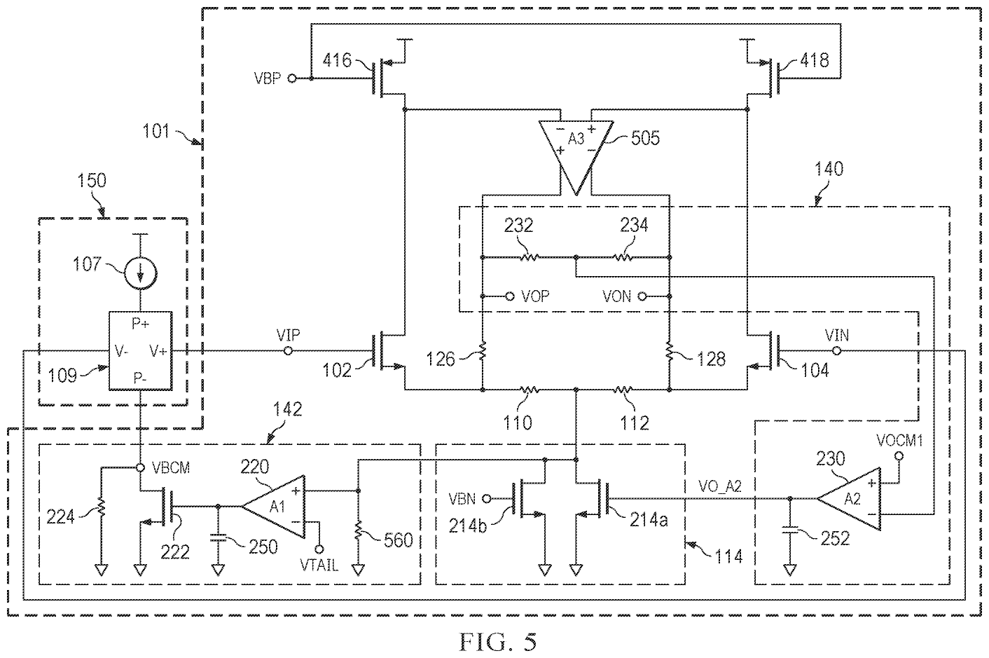

FIG. 5 illustrates another circuit diagram for an electrical system. The sensor circuit 150 and amplifier 101 are generally consistent with the features of FIGS. 1-2, with like reference numerals being labeled with the same reference numbers, but including additional features. In FIG. 5, a class AB op amp driver 505 with rail-to-rail output swing capability has replaced the feedback transistors 106, 108 of FIG. 2. A start-up resistor 560 is also added in parallel with the tail current transistors 214a and 214b to aid start up.

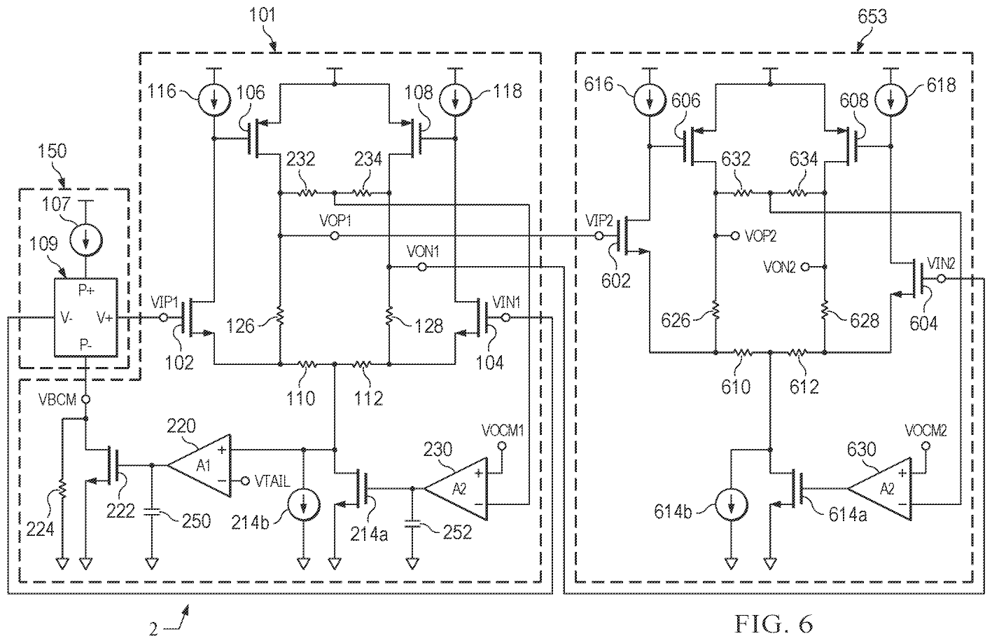

FIG. 6 illustrates another circuit diagram for an electrical system. The sensor circuit 150 and amplifier 101 are generally consistent with the features of FIGS. 1-2, with like reference numerals being labeled with the same reference numbers, but including additional features. In FIG. 6, a second amplifier 653 has a differential input (VIP2, VIN2) coupled to the differential output (VOP1, VON1) of the first amplifier for more gain amplification. In the illustrated example, second amplifier 653 is substantially the same as amplifier 101 of FIG. 2 except that the second amplifier 653 does not include the input common-mode control in the second stage. Thus, in the second amplifier 653, transistors 602, 604, 606, 608, 614a, and 614b have the same arrangement and function as transistors 102, 104, 106, 108, 214a, 214b, respectively, of FIG. 2. Similarly, resistors 610, 612, 626, 628, 632, and 634 have the same arrangement and function as resistors 110, 112, 126, 127, 232, and 234 of FIG. 2; and current sources 616, 618 have the same arrangement and function as current sources 116, 118, of FIG. 2. In other examples, the second amplifier 653 can take any form and thus, the circuit shown for 653 is merely an example. Thus, this example implements a two-stage amplifier architecture by cascading two example amplifiers, as shown in previous FIGS. In an example, only the first-stage has the input common-mode control. Example complimentary implementations can also be constructed with different combinations whereby the first stage and/or the second stage are complementary to the amplifier in FIG. 6.

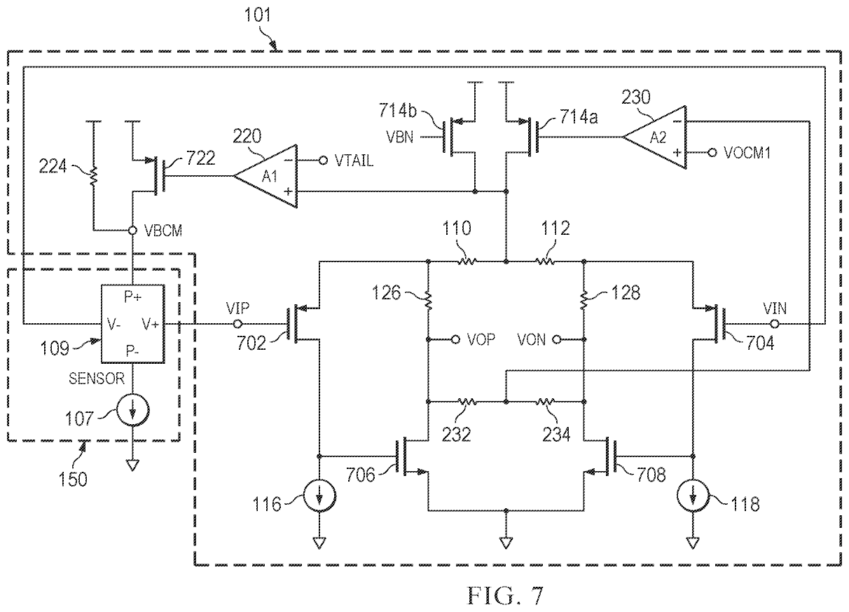

FIG. 7 illustrates another circuit diagram for an electrical system. The sensor circuit 150 and amplifier 101 are generally consistent with the features of FIGS. 1-2, with like reference numerals being labeled with the same reference numbers, but including additional features. FIG. 7 is a circuit diagram of another example amplifier architecture. This example architecture is a complementary implementation relative to FIG. 2. Thus, in FIG. 7, the NMOS transistors 102, 104, 214a, 214b, and 222 of FIG. 2 are replaced with PMOS transistors 702, 704, 714a, 714b, and 722, respectively. Similarly, the PMOS transistors 106, 108 of FIG. 2 are replaced with NMOS transistors 706, 708. The DC supply terminals (e.g., VDD and VSS) are also flipped relative to FIG. 2 to achieve the complementary implementation shown in FIG. 7

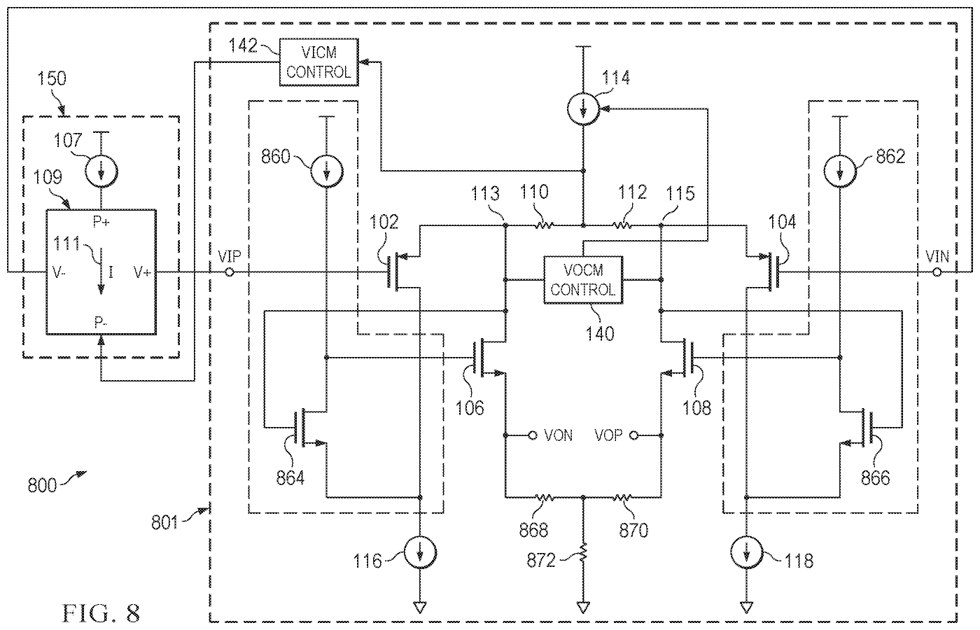

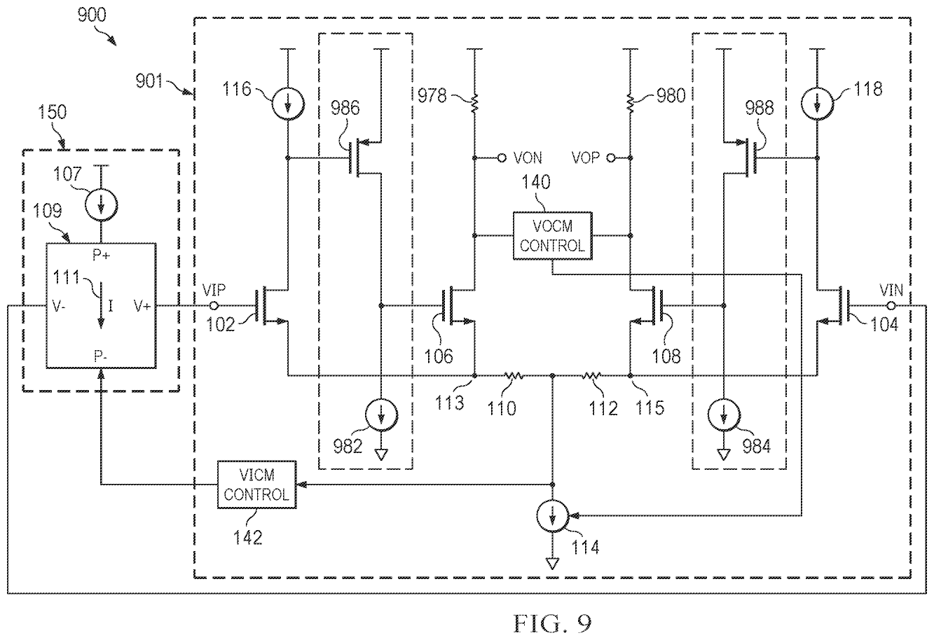

FIG. 8 and FIG. 9 show two other example electrical systems 800, 900 that can make use of other amplifiers (e.g., 801, 901) to replace the amplifier 101 of FIG. 2. However, the amplifier 101 of FIG. 2 is a streamlined and compact example that reduces cost and improves circuit stability. FIG. 8 and FIG. 9 illustrate that additional current sources 860, 862 and transistors 864, 866 may be added, but the operation principle is still the same as FIG. 1B and FIG. 2. Adding more transistors/current sources may increase the cost and/or degrade the circuit stability due to additional internal feedback loops. However, the amplifiers architecture may still provide at least some benefits over other amplifier architectures, especially when including examples of the VICM control circuit 142 and/or VOCM control circuit 142. Thus, 102, 104, 106, 108, 110, 112, 114, and 116 operate similarly in FIG. 8 and FIG. 9 as in FIG. 2. These other examples swap the locations of the various components. Moreover, amplifiers 801, 901 can also include VOCM control circuit 140 and/or VICM control circuit 142, for example as previously illustrated and described.

In FIG. 8, the amplifier 801 includes a pair of input differential transistors 102, 104 each having first and second terminals and each having a control terminal. The control terminals of the pair of input differential transistors 102, 104 correspond to a differential input (VIP, VIN) of the amplifier. A pair of feedback transistors 106, 108 each have first and second terminals and each have a control terminal. The first terminals of the feedback transistors 106, 108 correspond to a differential output (VOP, VON) of the amplifier.

The control terminals of the feedback transistors 106, 108 are respectively coupled to the first terminals of the input differential transistors 102, 104 via transistors 864, 866, respectively. The control terminals of the feedback transistors 106, 108 are also coupled to a pair of current sources 116, 118, respectively via transistors 864, 866, respectively. The first terminals of the input differential transistors 102, 104 are also coupled to the pair of current sources 116, 118, respectively. The differential output terminals (VOP, VON) are respectively coupled to first terminals of first and second gain setting resistors 110, 112 via transistors 106, 108. The second terminals of the input differential transistors 102, 104 are also respectively coupled to first terminals of first and second gain setting resistors 110, 112. Second terminals of the gain setting resistors 110, 112 are coupled to one another, and are coupled to a first terminal of a tail current circuit 114. Additional gain setting resistors 868, 870, 872 are also present. Additional current sources 860, 862, and additional control transistors 864, 866 are also included. The first additional control transistor 864 has a first terminal coupled to the current source 116, and a second terminal coupled to the current source 860 and coupled to the control terminal of transistor 106. The control terminal of transistor 864 is coupled to the second terminal of transistor 106. The second additional control transistor 866 has a first terminal coupled to the current source 118, and a second terminal coupled to the current source 862 and coupled to the control terminal of transistor 108. The control terminal of transistor 866 is coupled to the second terminal of transistor 108.

FIG. 9 is a circuit diagram of another electrical system 900 including example amplifier 901. The amplifier 901 includes a pair of input differential transistors 102, 104 each having first and second terminals and each having a control terminal. The control terminals of the pair of input differential transistors 102, 104 correspond to a differential input (VIP, VIN) of the amplifier. A pair of feedback transistors 106, 108 each have first and second terminals and each have a control terminal. The first terminals of the feedback transistors 106, 108 correspond to a differential output (VOP, VON) of the amplifier. The control terminals of the feedback transistors 106, 108 are respectively coupled to the first terminals of the input differential transistors 102, 104 via transistors 986, 988. The control terminals of the feedback transistors 106, 108 and the first terminals of the input differential transistors 102, 104 are also coupled to a pair of current sources 116, 118, respectively. The differential output terminals (VOP, VON) are also respectively coupled to first terminals of first and second gain setting resistors 110, 112 via transistors 106, 108. The second terminals of the input differential transistors 102, 104 are also respectively coupled to first terminals of first and second gain setting resistors 110, 112. Second terminals of the gain setting resistors 110, 112 are coupled to one another, and are coupled to a first terminal of a tail current circuit 114. Additional gain setting resistors 978, 980 are also present. Additional current sources 982, 984, and additional control transistors 986, 988 are also included. The first additional control transistor 986 has a control terminal coupled to the current source 116, and a second terminal coupled to the current source 982 and coupled to the control terminal of transistor 106. The second additional control transistor 988 has a control terminal coupled to the current source 118, and a second terminal coupled to the current source 984 and coupled to the control terminal of transistor 108.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. In other cases, the devices described herein are “configurable to” perform a task or function, meaning that the hardware present in the device is suitable to be programmed after manufacturing to perform the function via firmware and/or software programming of the device, and the firmware and/or software is not included at the time of manufacture.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor, a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other examples, additional or fewer features may be incorporated into the integrated circuit. Also, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of that parameter. Modifications are possible in the described examples, and other implementations are possible, within the scope of the claims.

What is claimed is:

1. An amplifier having a differential input and a differential output, comprising:
a first transistor having a first terminal, second terminal, and a control terminal, the first terminal of the first transistor coupled to a first current source, and the control terminal of the first transistor corresponding to a first input terminal of the differential input;
a second transistor having a first terminal, second terminal, and a control terminal, the first terminal of the second transistor coupled to a second current source, and the control terminal of the second transistor corresponding to a second input terminal of the differential input;
a third transistor having a first terminal, second terminal, and a control terminal, the first terminal of the third transistor coupled to the second terminal of the first transistor and corresponding to a first output terminal of the differential output, and the control terminal of the third transistor coupled to the first terminal of the first transistor;
a fourth transistor having a first terminal, second terminal, and a control terminal, the first terminal of the fourth transistor coupled to the second terminal of the second transistor and corresponding to a second output terminal of the differential output, and the control terminal of the fourth transistor coupled to the first terminal of the second transistor;
a first resistor having a first terminal and a second terminal, the first terminal of the first resistor coupled to the second terminal of the first transistor and coupled to the first terminal of the third transistor;
a second resistor having a first terminal and a second terminal, the first terminal of the second resistor coupled to the second terminal of the second transistor and coupled to the first terminal of the fourth transistor; and
a current circuit coupled to the second terminal of the first resistor and coupled to the second terminal of the second resistor.

2. The amplifier of claim 1, further comprising:
a third resistor having a first terminal and second terminal, the first terminal of the third resistor coupled to the first terminal of the third transistor and the second terminal of the third resistor coupled to the second terminal of the first transistor; and
a fourth resistor having a first terminal and second terminal, the first terminal of the fourth resistor coupled to the first terminal of the fourth transistor and the second terminal of the fourth resistor coupled to the second terminal of the second transistor.

3. The amplifier of claim 1, further comprising:
a voltage output common-mode control circuit having an input coupled to the differential output of the amplifier, and having an output coupled to a control terminal of the current circuit; and
a voltage input common-mode control circuit having an input coupled to the current circuit, and having an output coupled to the differential input of the amplifier.

4. The amplifier of claim 1, further comprising:
a fifth resistor having a first terminal and second terminal, the first terminal of the fifth resistor coupled to the first terminal of the third transistor; and
a sixth resistor having a first terminal and second terminal, the first terminal of the sixth resistor coupled to the first terminal of the fourth transistor and the second terminal of the sixth resistor coupled to the second terminal of the fifth resistor.

5. The amplifier of claim 4, further comprising:
a control amplifier having an input coupled to the second terminal of the fifth resistor and second terminal of the sixth resistor, and having an output coupled to a control terminal of the current circuit.

6. The amplifier of claim 1, further comprising:
a sixth transistor having a first terminal, a second terminal, and a control terminal, the first terminal of the sixth transistor coupled to the first terminal of the first transistor, and the control terminal of the sixth transistor coupled to the second terminal of the third transistor; and
a seventh transistor having a first terminal, a second terminal, and a control terminal, the first terminal of the seventh transistor coupled to the first terminal of the second transistor and the control terminal of the seventh transistor coupled to the second terminal of the fourth transistor.

7. The amplifier of claim 1, further comprising:
an eighth transistor having a first terminal, a second terminal, and a control terminal, the control terminal of the eighth transistor coupled to the first terminal of the first transistor and the first terminal of the eighth transistor coupled to the control terminal of the third transistor; and
a ninth transistor having a first terminal, a second terminal, and a control terminal, the control terminal of the ninth transistor coupled to the first terminal of the second transistor and the first terminal of the ninth transistor coupled to the control terminal of the fourth transistor.

8. The amplifier of claim 1, further comprising:
a second amplifier stage having an input coupled to the differential output.

9. An amplifier, comprising:
a pair of first transistors each having first and second terminals and each having a control terminal, the control terminals of the pair of first transistors corresponding to a differential input of the amplifier;
a pair of second transistors each having first and second terminals and each having a control terminal, the first terminals of the pair of second transistors corresponding to a differential output of the amplifier, the control terminals of the pair of second transistors are respectively coupled to the first terminals of the pair of first transistors;
a pair of current sources are respectively coupled to the control terminals of the pair of second transistors and the first terminals of the pair of first transistors;
a pair of first resistors having first terminals that are respectively coupled to the second terminals of the pair of first transistors and that are also respectively coupled to the differential output, the pair of first resistors having second terminals that are coupled to one another; and
a tail current transistor having a first terminal coupled to the second terminals of the pair of first resistors and a second terminal coupled to a DC supply.

10. The amplifier of claim 9, further comprising:
a voltage output common-mode control circuit having an input coupled to the differential output of the amplifier, and having an output coupled to a control terminal of the tail current transistor.

11. The amplifier of claim 10, wherein the voltage output common-mode control circuit is configured to adjust a current through the tail current transistor responsive to a differential output signal on the differential output of the amplifier.

12. The amplifier of claim 11, wherein the voltage output common-mode control circuit comprises:
a pair of second resistors coupled in series between the first terminals of the pair of second transistors, wherein a common output node is arranged between the pair of second resistors; and
a control amplifier having a first input coupled to the common output node, a second input coupled to a voltage output common output mode threshold, and an output coupled to a control terminal of the current tail transistor.

13. The amplifier of claim 9, further comprising:
a voltage input common-mode control circuit having an input coupled to the differential output of the second terminals of the pair of first resistors, and having an output coupled to the differential input of the amplifier.

14. The amplifier of claim 13, wherein the voltage input common-mode control circuit comprises:
a control amplifier having a first input coupled to the current tail transistor, a second input coupled to a voltage tail threshold, and an output; and
a transistor having a control terminal coupled to the output of the control amplifier.

15. The amplifier of claim 13, wherein the voltage input common-mode control circuit is configured to adjust an input signal provided to the differential input of the amplifier responsive to current level and/or voltage level on the tail current transistor.

16. An amplifier having a differential input and a differential output, comprising:
a first transistor having a first terminal, second terminal, and a control terminal, the first terminal of the first transistor coupled to a first current source, and the control terminal of the first transistor corresponding to a first input terminal of the differential input;
a second transistor having a first terminal, second terminal, and a control terminal, the first terminal of the second transistor coupled to a second current source, and the control terminal of the second transistor corresponding to a second input terminal of the differential input;
a third transistor having a first terminal, second terminal, and a control terminal, the first terminal of the third transistor coupled to the second terminal of the first transistor, and the control terminal of the third transistor coupled to the first terminal of the first transistor;
a fourth transistor having a first terminal, second terminal, and a control terminal, the first terminal of the fourth transistor coupled to the second terminal of the second transistor, and the control terminal of the fourth transistor coupled to the first terminal of the second transistor;
a first resistor having a first terminal and a second terminal, the first terminal of the first resistor coupled to the second terminal of the first transistor and coupled to the first terminal of the third transistor;
a second resistor having a first terminal and a second terminal, the first terminal of the second resistor coupled to the second terminal of the second transistor and coupled to the first terminal of the fourth transistor, the second terminal of the second resistor coupled to the second terminal of the first resistor;
a voltage output common-mode control circuit having an input and an output, the input of the voltage output common-mode control circuit coupled to the differential output of the amplifier; and
a voltage input common-mode control circuit having an input and an output, the input of the voltage input common-mode control circuit coupled to the output of the voltage output common-mode control circuit, and the output of the voltage input common-mode control circuit coupled to the differential input of the amplifier.

17. The amplifier of claim 16, further comprising:
a third resistor having a first terminal and second terminal, the first terminal of the third resistor coupled to the first terminal of the first transistor and the second terminal of the third resistor coupled to the first terminal of the first resistor;
a fourth resistor having a first terminal and second terminal, the first terminal of the fourth resistor coupled to the first terminal of the fourth transistor and the second terminal of the fourth resistor coupled to the first terminal of the second resistor; and
wherein the voltage output common-mode control circuit comprises:
a pair of output common-mode sensing resistors coupled between the first terminals of the third and fourth transistors, wherein a common output node is arranged between the pair of output common-mode sensing resistors; and
a control amplifier having a first input coupled to the common output node, a second input coupled to a voltage output common output mode threshold, and an output coupled to the voltage input common-mode control circuit.

18. The amplifier of claim 16, wherein the voltage input common-mode control circuit comprises:
a second control amplifier having a first input terminal, a second input terminal, and an output terminal, the first input terminal of the second control amplifier coupled to the second terminal of the first resistor and coupled to the second terminal of the second resistor; and
a fifth transistor having a first terminal, a second terminal, and a control terminal, the first terminal of the fifth transistor coupled to the output terminal of the second control amplifier.

19. The amplifier of claim 16, further comprising:
a sensor circuit coupled between the output of the voltage input common-mode control circuit and the differential input.

20. The amplifier of claim 19, wherein the sensor circuit comprises a Hall-effect sensor, a magneto-resistance sensor, or gauge-stress sensor.
